(19) United States
(12) Patent Application Publication
(10) Pub. No.: US 2007/0200160 A1
(43) Pub. Date: Aug. 30, 2007

(54) Semiconductor device and method of fabricating the same

(76) Inventors: Hyung-Suk Jung, Suwon-si (KR); Jong-Ho Lee, Suwon-si (KR); Ha-Jin Lim, Seoul (KR); Mi-Young Yu, Jeongeup-si (KR)

Correspondence Address: F. CHAU & ASSOCIATES, LLC, 130 WOODBURY ROAD, WOODBURY, NY, 11797, US

(21) Appl. No.: 11/650,290

(22) Filed: Jan. 5, 2007

(30) Foreign Application Priority Data
Jan. 6, 2006 (KR) 10-2006-0001665

(51) Int. Cl. H01L 29/94

(52) U.S. Cl. 257/310

(57) ABSTRACT

A semiconductor device includes a semiconductor substrate comprising an active area where a first conductive channel is formed, a gate electrode formed on the active area formed on the semiconductor substrate and a gate dielectric layer interposed between the active area and the gate electrode. The semiconductor device further includes a charge generating layer formed along the interface between the active area and the gate dielectric layer on the semiconductor substrate so that fixed charges are generated around the interface.

### CROSS-REFERENCE TO RELATED PATENT APPLICATION

This application claims the benefit of Korean Patent Application No. 10-2006-0001665, filed on Jan. 6, 2006, the disclosure of which is hereby incorporated by reference herein in its entirety.

### BACKGROUND OF THE INVENTION

1. Technical Field

The present disclosure relates to a semiconductor device and to a method of fabricating the same, and more particularly, to a semiconductor device comprising a metal oxide semiconductor (MOS) transistor and to a method of fabricating the same.

2. Description of the Related Art

As the integration density of semiconductor devices has increased and the feature sizes of metal oxide semiconductor field effect transistors (MOSFETs) have decreased, the lengths of gates and channels formed underneath the gates have likewise decreased. As a result, it may be necessary to form a thin gate dielectric layer to increase the capacitance between the gate and the channel and to improve the operational characteristics of transistors. However, a commonly used gate dielectric layer formed of materials such as, for example, silicon dioxide or silicon oxynitride may have physical limitations, particularly in terms of its electrical properties, when its thickness is decreased. Accordingly, it thus may be difficult to form a reliable thin gate dielectric layer.

Therefore, methods have been actively researched in an attempt to avoid the above-mentioned limitations of conventionally used gate dielectric layers by seeking to replace a typical gate oxide material such as silicon dioxide or silicon oxynitride with a material having a high dielectric constant (e.g., a high k material). A high-k material is capable of maintaining a thin equivalent oxide thickness and decreasing leakage current between a gate electrode and a channel region.

However, in the case of using a high-k material as the gate dielectric layer of a MOSFET, the electron mobility may decrease in a channel region formed underneath the gate dielectric layer, due to a plurality of bulk traps and interface traps occurring at an interface between a substrate and the gate dielectric layer. Also, compared with the gate dielectric layer based on silicon dioxide or silicon oxynitride, the threshold voltage (Vt) of the gate dielectric layer including the high-k material may increase to an undesirable level.

Accordingly, several attempts have been made to obtain a Vth having a desired level by performing channel engineering such as, for example, channel ion-implantation or the like on a gate dielectric layer formed of high-k materials. However, these attempted methods may still provide other difficulties such as, for example, enlarging of Drain Induced Barrier Lowering (DIBL) and Breakdown Voltage between Drain and Source (BVDS). In addition, in a CMOS transistor having an n-channel MOSFET and a p-channel MOSFET connected to each other, the various Vth values are measured depending on high-k materials used to form the gates of an n-channel MOS (NMOS) transistor and a p-channel MOS (PMOS) transistor. For example, when the gate dielectric layer is formed of a high-K material such as a hafnium (Hf)-based oxide and a gate electrode is formed of polysilicon, the NMOS transistor has a Vth similar to the situation in which a gate dielectric layer formed of nitrided SiO₂ is applied, but the PMOS transistor has an abnormally large Vth value. In particular, when the gate electrode of a PMOS transistor is formed of tantalum nitride (TaN), the Vth value becomes much higher. As the control limit of the Vth value through general channel engineering is about 0.2 V, the polysilicon gate electrode and the metal gate electrode each have their limits when it comes to controlling the Vth just through channel engineering. Accordingly, the difficulty of an unbalanced Vth in the CMOS transistor needs to be overcome.

### SUMMARY OF THE INVENTION

The exemplary embodiments of the present invention provide a semiconductor device in which a gate dielectric layer is formed of high-k materials to provide reliability and a NMOS transistor and a PMOS transistor which each have a normal Vth to provide optimum mobility properties.

The exemplary embodiments of the present invention also provide a method for fabricating a semiconductor device in which a gate dielectric layer is formed of high-k materials to provide reliability and a NMOS transistor and a PMOS transistor which each have a normal Vth to provide optimum mobility properties.

In accordance with an exemplary embodiment of the present invention, a semiconductor device is provided. The semiconductor device includes a semiconductor substrate comprising an active area where a first conductive channel is formed, a gate electrode formed on the active area of the semiconductor substrate, a gate dielectric layer interposed between the active area and the gate electrode, and a charge generating layer formed along the interface between the active area and the gate dielectric layer on the semiconductor substrate so that fixed charges are generated around the interface.

The active area may be formed in an N-type well of the semiconductor substrate, the charge generating layer is formed along the interface in the N-type well, and the charge generating layer has a first lattice structure which is different from a second lattice structure of the semiconductor substrate in another part of the N-type well. The first lattice structure of the charge generating layer includes a dopant formed of fluorine (F), germanium (Ge) or a combination thereof.

The first conductive channel may be a P-type channel, and the charge generating layer comprises a dopant formed of F, Ge or combinations thereof. Negative fixed charges may exist around the interface between the active area and the gate dielectric layer.

In accordance with an exemplary embodiment of the present invention, a semiconductor device is provided. The semiconductor device includes a semiconductor substrate including an active area of an n-channel metal oxide semiconductor (NMOS) transistor and an active area of a p-channel metal oxide semiconductor (PMOS) transistor, a first gate electrode formed on the active area of the NMOS transistor, a second gate electrode formed on the active area of the PMOS transistor, a first gate dielectric layer interposed between the semiconductor substrate and the first gate electrode, a second gate dielectric layer interposed between the semiconductor substrate and the second gate electrode, a nitrogen implantation region formed along an interface between the active area of the NMOS transistor and the first gate dielectric layer on the semiconductor substrate, and a charge generating layer formed along an interface between the active area of the PMOS transistor and the second gate dielectric layer on the semiconductor substrate.

In accordance with an exemplary embodiment of the present invention, a method of fabricating a semiconductor device is provided. The method includes forming a first conductive type well by ion-implanting a first dopant into a semiconductor substrate, forming a charge generating layer on the surface of the first conductive type well by implanting a fixed charge generation material in the first conductive type well, forming a gate dielectric layer on the charge generating layer, forming a gate electrode on the gate dielectric layer, and forming a source/drain region on both sides of the gate electrode in the first conductive type well by implanting a second impurity of a second conductive type into the first conductive type well.

The forming the charge generating layer may includes covering an upper surface of the first conductive type well with a protection layer before implanting the fixed charge generation material, and removing the protection layer after implanting the fixed charge generation material.

The first conductive type well may be an N-type well, the second conductive type well may be a P-type well, and the fixed charge generation material may be formed of F, Ge or combination thereof.

The method may further include heat-treating the semiconductor substrate for activating the fixed charge generation material after implanting the fixed charge generation material into the first conductive type well.

The method may further includes implanting a third dopant into the first conductive type well for regulating a threshold voltage of a transistor comprising the gate electrode before implanting fixed charge generation material into the first conductive type well.

In accordance with an exemplary embodiment of the present invention, a method of fabricating a semiconductor device is provided. The method includes preparing a semiconductor substrate comprising an active area of an n-channel metal oxide semiconductor (NMOS) transistor and an active area of a p-channel metal oxide semiconductor (PMOS) transistor, forming a nitrogen implantation region on only the active area of the NMOS transistor on the semiconductor substrate, forming a charge generating layer on only the active area of the PMOS transistor on the semiconductor substrate and forming a first gate dielectric layer and a second gate dielectric layer on the nitrogen implantation region on the active area of the NMOS transistor and the charge generating layer on the active area of the PMOS transistor respectively. The method further includes forming a first gate electrode and a second gate electrode on the gate dielectric layer on the active area of the NMOS transistor and the active area of the PMOS transistor respectively and forming a first source/drain region arranged at both sides of the first gate electrode on the active area of the NMOS transistor, and a second source/drain region arranged at both sides of the second gate electrode on the active area of the PMOS transistor.

According to exemplary embodiments of the present invention, the NMOS transistor and the PMOS transistor each realize a desired Vth by forming layers different from each other including specifying the materials in which Vth can be controlled to be a desired value on interfaces between the active area of the NMOS transistor region/the active area of the PMOS transistor and the gate dielectric layer. Accordingly, when a high integrated semiconductor is fabricated while having a gate dielectric layer formed of high-k materials, the NMOS transistor and the PMOS transistor can realize a desired Vth without degradation of mobility properties and reliability to thereby achieve a semiconductor device which provides optimum mobility properties.

### BRIEF DESCRIPTION OF THE DRAWINGS

Exemplary embodiments of the present invention can be understood in more detail from the following description taken in conjunction with the accompanying drawings in which:

FIGS. 1 through 8 are cross-sectional views illustrating sequential operations of a method of fabricating a semiconductor device according to an exemplary embodiment of the present invention;

FIG. 9 is a graph of the Vth property of a PMOS transistor fabricated using a method according to an exemplary embodiment of the present invention;

FIG. 10 is a graph of the mobility of carriers of a PMOS transistor fabricated using the method according to an exemplary embodiment of the present invention;

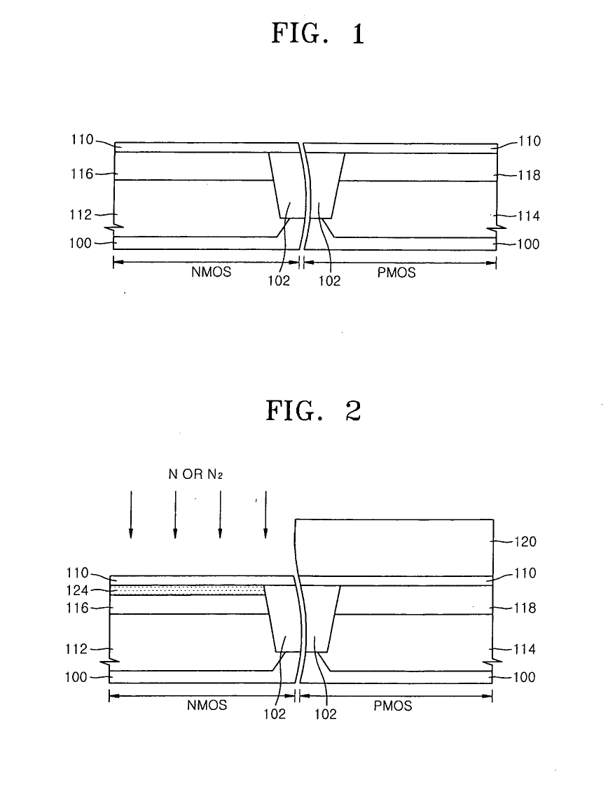

FIG. 1-1 is a graph of the Vth property of a PMOS transistor fabricated using a method according to an exemplary embodiment of the present invention;

FIG. 12 is a graph of the Vth property of a PMOS transistor fabricated using a method according to an exemplary embodiment of the present invention;

FIG. 13A is a negative bias temperature instability (NBTI) property graph of shifts in a Vth range with respect to stress time for various gate voltages applied to a PMOS transistor fabricated using a method according to an exemplary embodiment of the present invention;

FIG. 13B is a graph of shifts in a Vth range measured in the same manner as in FIG. 13A except that a sample of a PMOS transistor is fabricated using a method without an operation of implanting F;

FIG. 14 is a graph of a NBTI property of a PMOS transistor fabricated using a method according to an exemplary embodiment of the present invention

FIG. 15 is a graph of a Vth property of a PMOS transistor fabricated using the method according to an exemplary embodiment of the present invention;

FIG. 16 is a graph of mobility of carriers of the PMOS transistor fabricated using the method according to an exemplary embodiment of the present invention.

FIG. 17A is a negative bias temperature instability (NBTI) property graph of shifts in a Vth range with respect to stress time for various gate voltages applied to a PMOS transistor fabricated using a method according to an exemplary embodiment of the present invention; and

FIG. 17B is a graph of shifts in a Vth range measured in the same manner as in FIG. 17A except that a sample of a PMOS transistor is fabricated using a method without an operation of implanting germanium (Ge).

### DETAILED DESCRIPTION OF THE EXEMPLARY EMBODIMENTS OF THE INVENTION

The present invention will now be described more fully with reference to the accompanying drawings, in which exemplary embodiments of the invention are shown. The invention may, however, be embodied in many different forms and should not be construed as being limited to the exemplary embodiments set forth herein.

FIGS. 1 through 8 are cross-sectional views illustrating sequential operations of a method of fabricating a semiconductor device according to an exemplary embodiment of the present invention.

Referring to FIG. 1, a semiconductor substrate 100, which includes a NMOS transistor region (in FIGS. 1 through 8 indicated as “NMOS”) and a PMOS transistor region (in FIGS. 1 through 8 indicated as PMOS), is prepared. To define respective active areas on the NMOS transistor region and the PMOS transistor region, an isolation film 102 is formed on the semiconductor substrate 100. In the current exemplary embodiment, the isolation film 102 may be formed using, for example, a shallow trench isolation (STI) method, but may also be formed using other methods such as a local oxidation of silicon (LOCOS) method, or the like.

A protection layer 110 is formed on the semiconductor substrate 100 to cover the active areas defined by the isolation film 102. The protection layer 110 minimizes damage caused to the semiconductor substrate 100 when dopants or other materials are implanted into the semiconductor substrate 100. The protection layer 110 may be formed using, for example, a thermal oxidation method, and may be a silicon dioxide layer having a thickness of about 100 angstroms (Å). The protection layer 110 may be omitted on occasion.

A P-type first well 112 and an N-type second well 114 are formed in the NMOS transistor region and the PMOS transistor region, respectively, using a general method of forming a well. In addition, to adjust each threshold voltage Vth, an NMOS channel ion implantation region 116 and a PMOS channel ion implantation region 118 are formed on the first well 112 and the second well 114 respectively using a general method. For example, the first well 112 may be formed by implanting P-type impurities such as boron (B) or boron difluoride (BF₂) into the NMOS transistor region of the semiconductor substrate 100 through the protection layer 110. The NMOS channel ion implantation region 116 may be formed by implanting P-type impurities having a low concentration into the NMOS transistor region through the protection layer 110. The second well 114 may be formed by implanting N-type impurities such as, for example, phosphorus (P) or arsenic (As) into the PMOS transistor region of the semiconductor substrate 100 through the protection layer 110. The channel ion implantation region for PMOS 118 may be formed by implanting, for example, N-type impurities having a low concentration into the PMOS transistor region of the semiconductor substrate 100 through the protection layer 110. The channel ion implantation region for NMOS 116 and the channel ion implantation region for PMOS 118 may on occasion be omitted.

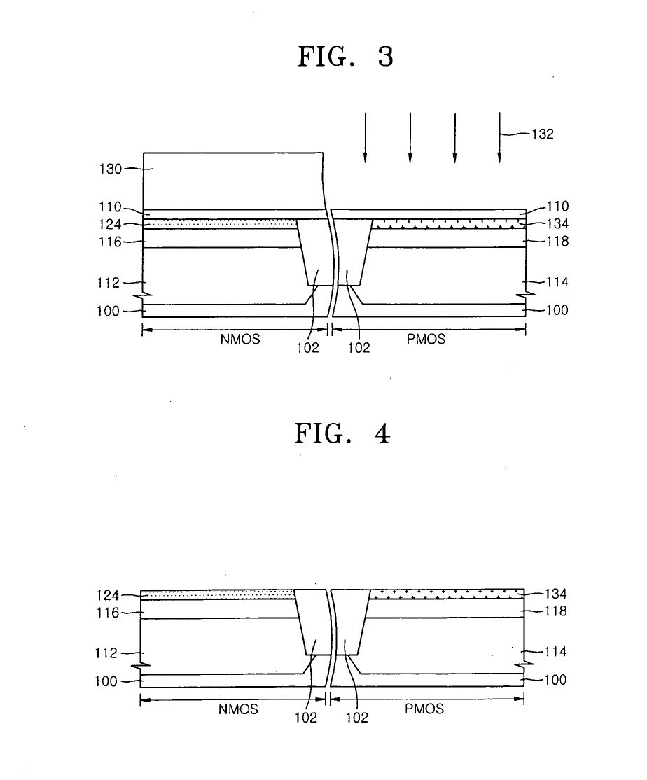

Referring to FIG. 2, a first photoresist pattern 120, through which only the NMOS transistor region is exposed, is formed on the PMOS transistor region. A nitrogen implantation region 124 is formed on the active area of the NMOS transistor by implanting, for example, nitrogen (N) or nitrogen molecules (N₂) into the first well 112 through the protection layer 110 using the first photoresist pattern 120 as a mask.

When the nitrogen implantation region 124 is formed right after the first well 112 and the NMOS channel ion implantation region 116 are formed, the first photoresist pattern 120 does not necessarily have to be additionally formed. That is, a photoresist pattern used in the ion-implanting operation for forming the first well 112 may be used again as the first photoresist pattern 120.

The nitrogen implantation region 124 may be formed using, for example, an ion implantation method, a heat treatment under a nitrogen containing atmosphere such as an ammonia atmosphere, or a plasma-enhanced nitridation method. The nitrogen implantation region 122 may be formed by implanting, for example, N or N₂ into the semiconductor substrate 100 with a dose in the range of about 1E14 through about 1E16 ion/cm² and energy in the range of about 30 KeV. For example, when the protection layer 110 is omitted, the nitrogen implantation region 122 may be formed by implanting N or N₂ into the semiconductor substrate 100 with a dose of about 1E15 ion/cm² and energy in the range of about 10 KeV. On the other hand, when the protection layer 110 is not omitted, the nitrogen implantation region 124 may be formed by implanting N or N₂ into the semiconductor substrate 100 with a dose of about 1E15 ion/cm² and an energy of about 30 KeV.

N or N₂, which is implanted into the semiconductor substrate 100, is activated by a first heat treatment. For example, the first heat treatment can be performed under a temperature in the range of about 700 through about 1100° C. for several seconds, for example, about 5 through about 15 seconds.

The operation of forming a nitrogen implantation region 124, which is described with reference to FIG. 2, is not necessarily performed, and can be omitted on occasion.

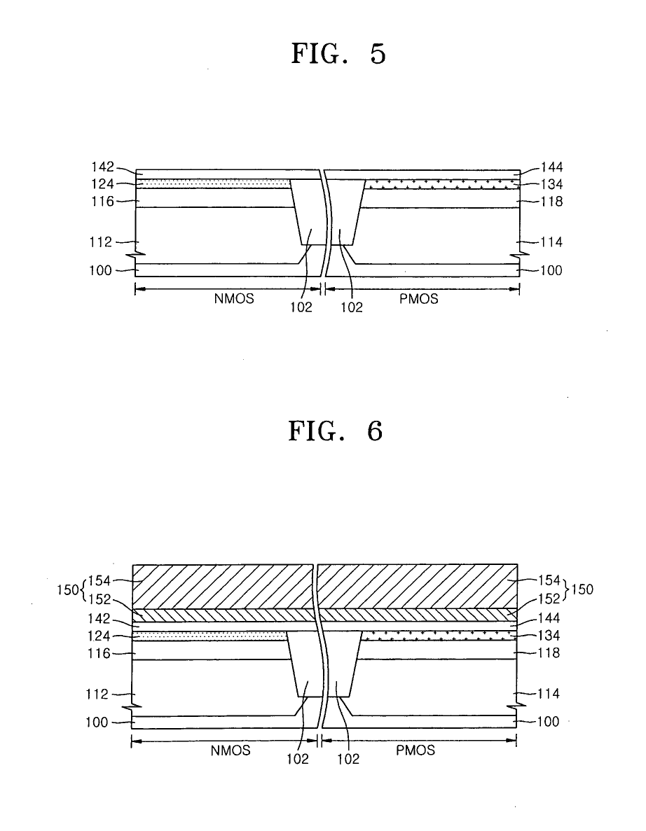

Referring to FIG. 3, when the first photoresist pattern 120 is removed, a second photoresist pattern 130, through which only the PMOS transistor region is exposed, is formed on the NMOS transistor region. A charge generating layer 134 is formed on the active area of the PMOS transistor region by implanting fixed charge generation material 132 into the second well 114 through the protection layer 110 using the second photoresist pattern 130 as a mask.

When the charge generating layer 134 is formed right after the second well 114 and the NMOS channel ion implantation region 118, the second photoresist pattern 130 does not necessarily have to be additionally formed. That is, a photoresist pattern used in the ion-implanting operation for forming the second well 114 may be used again as the second photoresist pattern 130.

The charge generating layer 134 may be formed by implanting the fixed charge generation material 132 composed of fluorine (F), germanium (Ge), or combination thereof into the semiconductor substrate 100. For example, the charge generating layer 134 may be formed by implanting the fixed charge generation material 132 into the semiconductor substrate 100 with a dose in the range of about 1E14 through about 1E16 ion/cm² and energy in the range of about 5 through about 50 KeV. For example, the charge generating layer 134 may be formed by implanting the fixed charge generation material 132 into the semiconductor substrate 100 with a dose in the range of about 5.0E14 through about 5.0E15 ion/cm² and an energy of about 5 through about 30 KeV. The energy, provided when implanting the fixed charge generation material 132 can be adjusted according to whether or not the protection layer 110 exists. When the fixed charge generation material 132 is implanted to form the charge generating layer 134, if the dose is too low or high, the range of a shift in Vth for obtaining a Vth required for a PMOS transistor may be too small or great. This is not preferable for obtaining desired electrical properties. Accordingly, the dose and energy can be determined so that the fixed charge generation material 132 is implanted within the above defined ranges according to the desired Vth shift range.

The fixed charge generation material 132 implanted into the semiconductor substrate 10 may be activated using a second heat treatment. For example, the second heat treatment may be performed under a temperature in the range of about 700 through about 1100° C. for several seconds, for example, about 5 through about 15 seconds:

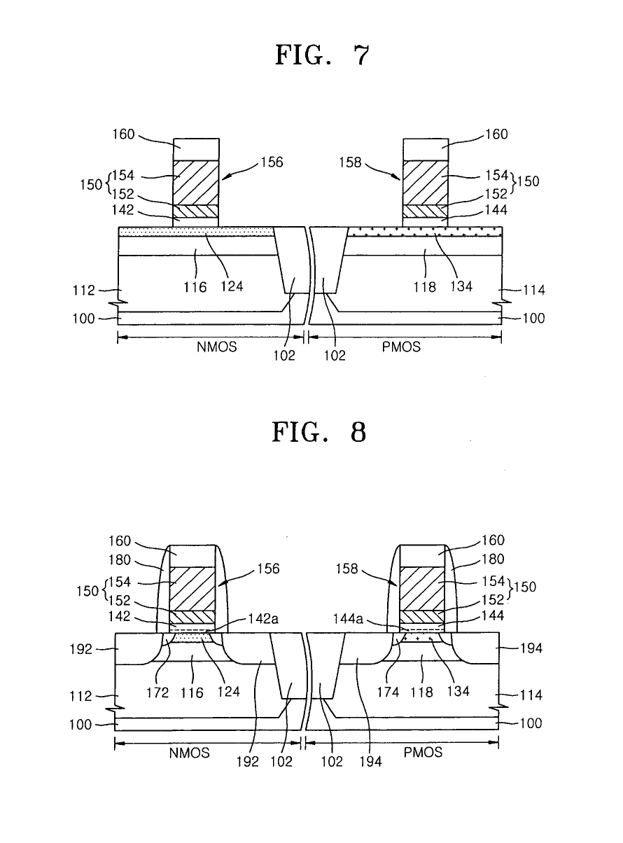

Referring to FIG. 4, the nitrogen implantation region 124 and the charge generating layer 134, which are formed on the active area of the semiconductor substrate 100, are exposed by removing the second photoresist pattern 130 and the protection layer 110.

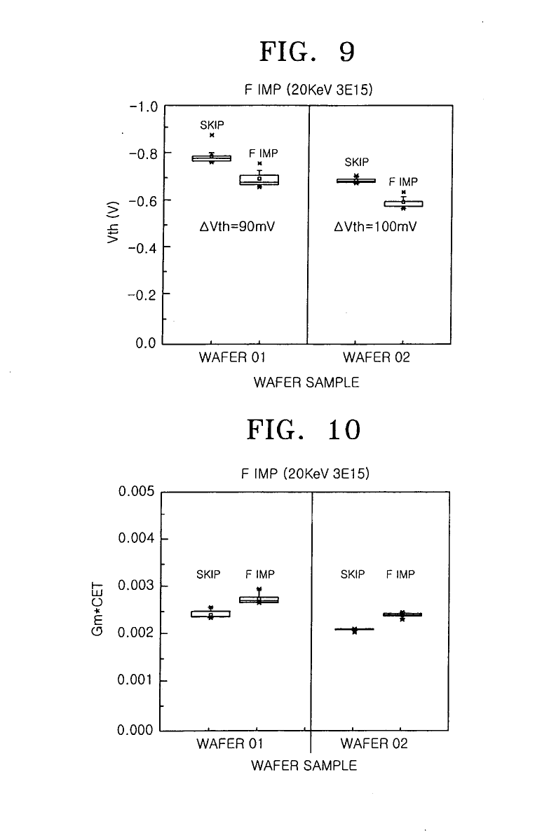

Referring to FIG. 5, on the active area of the NMOS transistor region and the active area of the PMOS transistor region, a first gate dielectric layer 142 and a second gate dielectric layer 144 are formed on the nitrogen implantation region 124 and the charge generating layer 134 respectively. The first gate dielectric layer 142 and the second gate dielectric layer 144 may each be formed to have a thickness in the range of about 10 through about 100 Å.

The first gate dielectric layer 142 and the second gate dielectric layer 144 may be formed of materials having a high dielectric constant. For example, the first gate dielectric layer 142 and the second gate dielectric layer 144 may each be formed of any one of the materialsselected from the group consisting of hafnium oxide (HfO₂), zirconium oxide (ZrO₂), aluminum oxide (Al₂O₃), titanium oxide (TiO₂), lanthanum oxide (La₂O₃), yttrium oxide (Y₂O₃), gadolinium oxide (Gd₂O₃), tantalum oxide (Ta₂O₅), aluminate and metal silicate, or combinations thereof. The first gate dielectric layer 142 and the second gate dielectric layer 144 are formed using, for example, an atomic layer deposition (ALD), chemical vapor deposition (CVD) or physical vapor deposition (PVD) method. An interface oxide layer growth which can be generated between the semiconductor substrate 100 and the first and second gate dielectric layers 142 and 144 can be minimized by performing a deposition for forming the first gate dielectric layer 142 and the second gate dielectric layer 144 under as low a temperature as possible. As the ALD method is performed under a relatively low temperature, the first gate dielectric layer 142 and the second gate dielectric layer 144 may be formed using the ALD method.

After the first gate dielectric layer 142 and the second gate dielectric layer 144 are formed, a third heat treatment may be performed on the semiconductor substrate 100. The third heat treatment may be performed under an atmosphere composed of, for example, nitrogen (N₂), oxygen (O₂), ammonia (NH₃), NH₃ plasma, or combinations thereof with a temperature in the range of about 700 through about 1100° C. for several seconds, for example, about 30 seconds. The impurities in the first gate dielectric layer 142 and the second gate dielectric layer 144 can be removed by the third heat treatment. The first gate dielectric layer 142 and the second gate dielectric layer 144 can also be densified by the third heat treatment. The third heat treatment may on occasion be omitted.

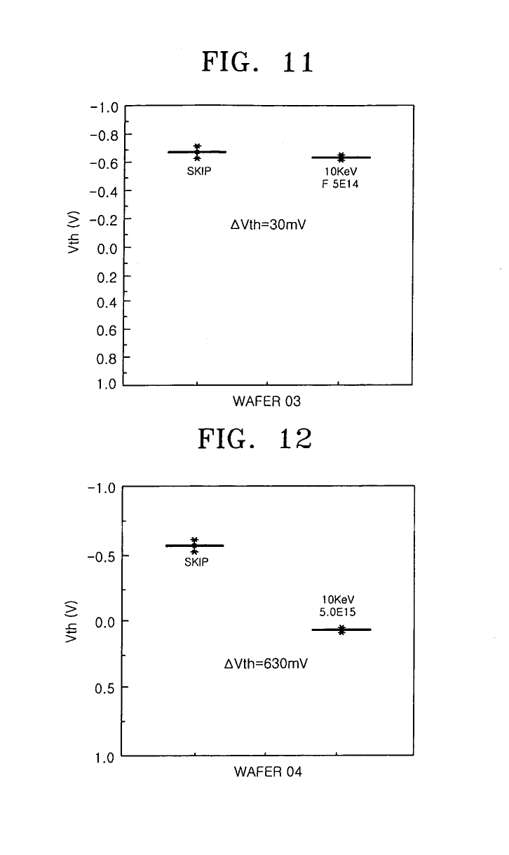

Referring to FIG. 6, conductive layers 150 for forming a gate electrode are formed on the first gate dielectric layer 142 and the second gate dielectric layer 144.

The conductive layers 150 may be formed of, for example, a metal, a metal nitride, a metal silicide, or combinations thereof. According to the current exemplary embodiment of the present invention, the conductive layers 150 are composed of dual layers, that is, the first conductive layer 152 and the second conductive layer 154. The first conductive layer 152 may be formed of, for example, titanium (Ti), tantalum (Ta), hafnium (Hf), zirconium (Zr), aluminum (Al), copper (Cu), tungsten (W), molybdenum (Mo), platinum (Pt), ruthenium Oxide (RuO), titanium nitride (tiN), tantalum nitride (TaN), hafnium nitride (HfN), zirconium nitride (ZrN), tungsten nitride (WN), molybdenum nitride (MoN), titanium aluminium nitride (TiAlN), tantalum aluminum nitride (TaAlN), titanium silicon nitride (TiSiN), tantalum silicon nitride (TaSiN), or a metal or metal nitride composed of combinations thereof. For example, the first conductive layer 152 may be formed of a metal nitride. The second conductive layer 154 may be formed of, for example, doped polysilicon, a metal, a metal silicide, or combinations thereof. For example, the first conductive layer 152 may be formed of TaN, and the second conductive layer 154 may be formed doped polysilicon. The first conductive layer 152 may be formed to have a thickness in the range of about 10 through about 100 Å. The second conductive layer 154 may be formed to have a thickness in the range of about 1000 through about 1500 Å.

Additionally, a fourth heat treatment may also be performed on the semiconductor substrate 100 before the second conductive layer 154 is formed after the first conductive layer 152 is formed. The specific conditions of the fourth heat treatment are the essentially the same as those of the third heat treatment as described above. Impurities such as, for example, carbon left in the first conductive layer 152 can be removed by the fourth heat treatment. The first conductive layer 152 can be densified also by the fourth heat treatment. The fourth heat treatment can on occasion be omitted.

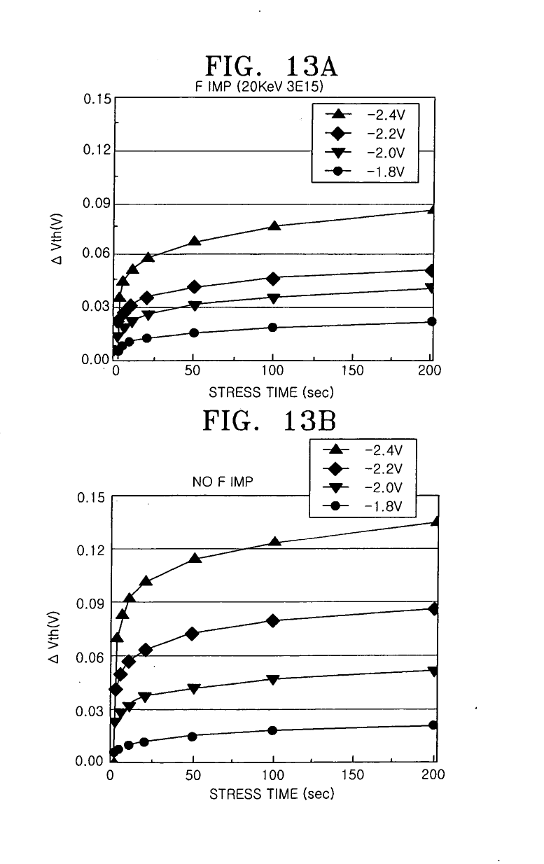

Referring to FIG. 7, hard mask patterns 160 are formed on the conductive layers 150. The hard mask patterns 160 may be formed of, for example, silicon nitride. A first gate electrode 156 and a second gate electrode 158 are formed on the first gate dielectric layer 142 and the second gate dielectric layer 144 formed on the semiconductor substrate 100 respectively by etching the conductive layer 150, the first gate dielectric layer 142 and the second gate dielectric layer 144 using the hard mask patterns 160 as etch masks.

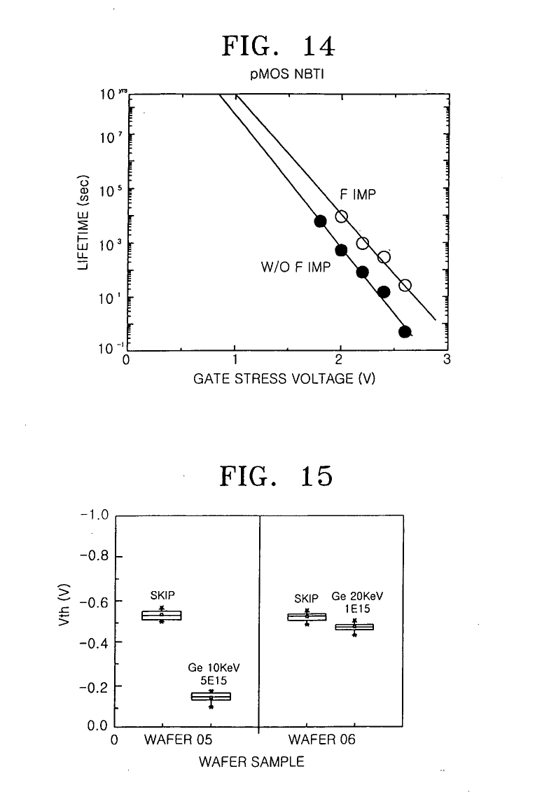

Referring to FIG. 8, on the NMOS transistor region, a first extension region 172 is formed by selectively implanting an N-type dopant having a low concentration into only the first well 112 using the hard mask patterns 160 and the first gate electrode 156 as etch masks. On the PMOS transistor region, a second extension region 174 is formed by selectively implanting a P-type dopant having a low concentration into only the second well 114 using the hard mask patterns 160 and the second gate electrode 158 as etch masks.

Insulating spacers 180 are formed on walls of the hard mask patterns 160 and gate electrodes 156 and 158. The insulating spacers 180 may be formed of, for example, a silicon dioxide, silicon nitride, silicon oxynitride, or combinations thereof.

Next, on the NMOS transistor region, first source/drain regions 192 are formed on both sides of the first gate electrode 156 by selectively implanting an N-type dopant into only the first well 112 using the hard mask pattern 160 and the insulating spacers 180 as etch masks. On the PMOS transistor region, second source/drain regions 194 are formed on both sides of the second gate electrode 158 by selectively implanting a P-type dopant into only the second well 114 using the hard mask pattern 160 and the insulating spacer 180 as an ion implantation mask.

After the first and second source/drain regions 192 and 194 are formed by ion-implanting, the ions implanted into the semiconductor substrate 100 may be activated by a fifth heat treatment on the semiconductor substrate 100. For example, the fifth heat treatment on the semiconductor substrate 100 may be performed at a temperature in the range of about 700 through about 1100 Å. On occasion, the fifth heat treatment can be omitted.

As described above, after the first gate dielectric layer 142 and the second gate dielectric layer 144 are formed on the nitrogen implantation region 124 of the NMOS transistor region and the charge generating layer 134 of the PMOS transistor region, respectively, the third, the fourth, or the fifth heat treatments are performed. As the third, the fourth, or the fifth heat treatments are performed, a thermal budget is imposed on the nitrogen implantation region 124 and charge generating layer 134 formed on the semiconductor substrate 100.

As the thermal budget is imposed on the nitrogen implantation region 124 and the charge generating layer 134, on the NMOS transistor region, nitrogen may be diffused from the nitrogen implantation region 124 into the first gate dielectric layer 142 to form a very thin nitrogen-containing insulating layer 142a at an interface between the nitrogen implantation region 124 and the first gate dielectric layer 142.

The nitrogen-containing insulating layer 142a is formed to have the same thickness as that of the first gate dielectric layer 142. On the NMOS transistor region, the nitrogen implantation region 124 and the nitrogen-containing insulating layer 142a are formed between the active area and first gate dielectric layer 142 formed on the semiconductor substrate 100, and thus Vth of the NMOS transistor employing a material having a high dielectric constant as the first gate dielectric layer 142 is lowered accordingly to adjust the Vth to a preferable value.

In addition, as the thermal budget is imposed on the nitrogen implantation region 124 and the charge generating layer 134, on the PMOS transistor region, a lattice structure formed on the semiconductor substrate 100 is different from that of other parts because of the charge generating layer 134. For example, when the charge generating layer 134 is formed by implanting fluorine (F) into the semiconductor substrate 100 formed of silicon, S—F bonds exist in the lattice structure of the substrate near a surface of the semiconductor substrate 100. Defects occurring at the interface between the active area of the PMOS transistor and the second gate dielectric layer 144, are passivated with Si—F by the S—F bonds. In addition, a fixed charge layer 144a containing negative fixed charges, is formed on the interface between the fixed charge layer 144a and the charge generating layer 134. Due to the negative fixed charges in the fixed charge layer 144a, when a voltage is applied to a gate electrode of the PMOS transistor, the mobility of carriers can be improved.

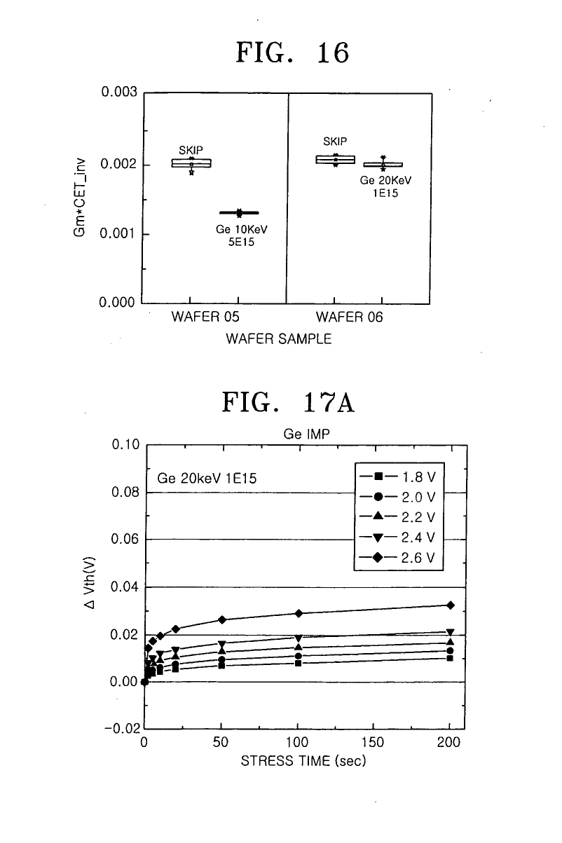

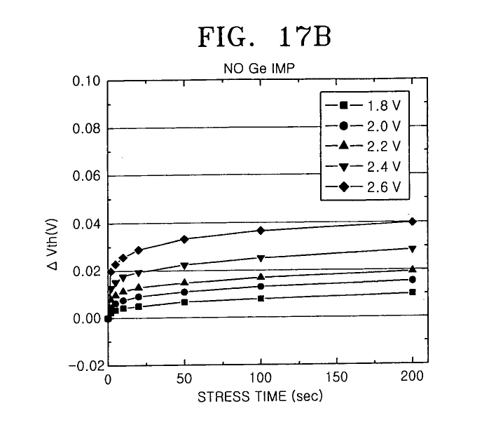

FIGS. 9 and 10 are graphs of electrical properties of a semiconductor device according to an exemplary embodiment of the present invention. In particular, FIG. 9 is a graph of a Vth property of a PMOS transistor fabricated using a method according to an embodiment of the present invention. FIG. 10 is a graph of the mobility of carriers of a PMOS transistor fabricated using the method according to an exemplary embodiment of the present invention.

For estimation of the electrical properties, a charge generating layer is formed by implanting F into an active area of a silicon substrate with a dose of about 3E15 ion/cm² and an energy of about 20 KeV. A gate dielectric layer formed of HfO₂ is formed on the charge generating layer to have a thickness of about 30 Å, and is then annealed at a temperature of about 950° C. for about 30 seconds. A gate electrode is formed on the gate dielectric layer in the form of a stack structure of a TaN layer having a thickness of about 40 Å and a polysilicon layer having a thickness of about 1500 Å. Here, the gate electrode includes word lines each having a width of about 1 micrometers (μm) and a length of about 10 μm. After a source/drain region is formed on both sides of the gated electrode to complete a PMOS transistor according to exemplary embodiments of the present invention, the completed PMOS transistor is estimated in view of the Vth property and the mobility of carriers.

Referring to FIGS. 9 and 10, “Wafer 01” and “Wafer 02” are samples of wafers used in the estimation. Data indicated as “SKIP” are results of a comparative example which is a PMOS transistor fabricated in the same manner as in a method according to exemplary embodiments of the present invention except that the operation of implanting F is omitted.

In the PMOS transistor fabricated using a method according to exemplary embodiments of the present invention, Vth is reduced by about 0.1 V without degradation of mobility.

In fabricating the semiconductor device recited in FIGS. 9 and 10, a reduction in a Vth range can be regulated into a desired range by changing a dose and energy used for implanting F. In the estimation of FIGS. 9 and 10, Vth of the PMOS transistor is reduced by implanting F into the semiconductor substrate, as F implanted into the semiconductor substrate comes to an acceptor like an interface state between the gate dielectric layer and the semiconductor substrate. In addition, the presence of F in a channel improves the mobility of carriers as relatively weak Si—H bonds formed at the interface between the semiconductor substrate and the gate dielectric layer are passivated into relatively strong Si—H bonds. Additionally, the mobility of carriers is improved as Si—O—Si bonds at the interface between the semiconductor substrate and the gate dielectric layer are substituted with Si—F bonds by implanting F, and simultaneously stress relaxation occurs around the interface. However, it is not desirable for too large a quantity of F to exist in the channel, as a distortion of CV curve may occur.

FIGS. 11 and 12 are graphs of electrical properties of a semiconductor device according to other exemplary embodiments of the present invention. For example, FIG. 11 is a graph for estimating a Vth property “wafer 03” which is a sample of a wafer fabricated in the same manner as the method described with reference to FIG. 9 except that F is implanted into the silicon substrate with a dose of about 5E14 ion/cm² and an energy of about 10 KeV. FIG. 12 is a graph for estimating a Vth property “Wafer 04” which is a sample of a wafer fabricated in the same manner as the method described with reference to FIG. 9 except that F is implanted into the silicon substrate with a dose of about 5E15 ion/cm² and energy of about 10 KeV.

Referring to FIG. 11, a Vth shift range in Wafer 03 is about 30 mV and it is very small. Referring to FIG. 12, it can be seen that a Vth shift range in Wafer 04 is 630 mV and it is very small. Vth is altered to a positive value. It is required that the dose and energy when implanting F be regulated to be at preferable levels taking into account variation in the parameters of elements included in the semiconductor device, to control a reduction in a Vth range of the PMOS transistor to a desired range.

FIGS. 13A and 13B are graphs of a reliability property of the PMOS transistor fabricated using a method according to another exemplary embodiment of the present invention. For example, FIG. 13A is a negative bias temperature instability (NBTI) property graph of shifts in a Vth range with respect to stress time, when gate voltages of about −1.8 V, about −2.0 V, about −2.2 V, and about −2.4 V are applied to the PMOS transistor fabricated in the same manner as in the method described with reference to FIG. 9, that is, the PMOS transistor fabricated by implanting F with a dose of about 3E15 ion/cm² and an energy of about 20 KeV. FIG. 13B is a graph of shifts in a Vth range measured in the same manner as in FIG. 13A except that a sample PMOS transistor is fabricated using a method without an operation of implanting F. Accordingly, the sample used in FIG. 13B is a comparative example.

Referring to FIGS. 13A and 13B, it can be seen that shifts in a Vth range with respect to stress time caused by application of gate voltages are relatively small.

FIG. 14 is a graph of an NBTI property of a PMOS transistor fabricated using a method according to another exemplary embodiment of the present invention. In particular, FIG. 14 shows expected lifetimes of samples of FIGS. 13A and 13B according to the gate stress voltage. Referring to FIG. 14, the “∘” symbol represent results of a sample used in FIG. 13A, that is, results of the present invention. The “•” symbol represents results of a sample used in FIG. 13B, that is, results of a comparative example.

It can be seen from FIG. 14 that as relatively strong Si—F bonds exist at the interface between the semiconductor substrate and the gate dielectric layer due to F implanted into the semiconductor substrate, the expected lifetime of the PMOS transistor according to exemplary embodiments of the present invention is long. That is, Si—O—Si bonds are altered to Si—F bonds at the interface between the semiconductor substrate and the gate dielectric layer, and simultaneously, stress relaxation occurs around the interface.

FIGS. 15 and 16 are graphs of electrical properties of a semiconductor device fabricated using a method according to another exemplary embodiment of the present invention. In particular, FIG. 15 is a graph of a Vth property of a PMOS transistor fabricated using a method according to an exemplary embodiment of the present invention, and FIG. 16 is a graph of the mobility of carriers of the PMOS transistor fabricated using a method according to an exemplary embodiment of the present invention.

For estimation, wafer samples (Wafer 05 and Wafer 06), which are used in FIGS. 15 and 16, are fabricated in the same manner as the method described with reference to FIGS. 9 and 10 except that Ge instead of F is implanted into the active area of the semiconductor substrate included in the PMOS transistor with a dose of about 5E15 ion/cm² and an energy of about 10 KeV (Wafer 05) in Wafer 05, and a dose of about 1E15 ion/cm² and an energy of about 20 KeV 15 in Wafer 06.

Referring to FIGS. 15 and 16, data indicated as “SKIP” are results of a comparative example which is the PMOS transistor fabricated in the same manner as in the method according to exemplary embodiments of the present invention except that the operation of implanting Ge is omitted.

It can be seen from FIGS. 15 and 16 that Vth of the PMOS transistor fabricated by implanting Ge into the active area of the semiconductor substrate is reduced, but the mobility property is degraded.

In fabricating the semiconductor device according to exemplary embodiments of the present invention, variable manufacturing parameters should be optimized to improve both the Vth property and the mobility property. For example, when F or Ge is implanted into the PMOS transistor region according to the desired Vth property and mobility property, it can be determined whether a protection layer may be formed on the semiconductor substrate or not. In addition, mobility degradation can be optimized by determining a dose and energy at which to infuse F or Ge.

FIGS. 17A and 17B are graphs of reliability properties of a PMOS transistor fabricated using a method according to another exemplary embodiment of the present invention. In particular, FIG. 17A is a NBTI property graph of shifts in a Vth range with respect to time for gate voltages of about 1.8 V, about 2.0 V, about 2.2 V, about 2.4 V, and about 2.6 V applied to the PMOS transistor fabricated implanting Ge with a dose of about 1E15 ion/cm² and an energy of about 20 KeV, and is similar to the estimating manner of Wafer 06 in FIG. 15. The sample used in FIG. 17B is a comparative example. FIG. 17B is a graph for estimating in the same manner as in FIG. 17A except that operation of implanting Ge is omitted.

It can be seen that in the PMOS transistor according to exemplary embodiments of the present invention, shifts in Vth range with respect to stress time caused by application of gate voltages are relatively small, and degradation of reliability according to an implanting Ge is not observed.

According to exemplary embodiments of the present invention, in fabricating a CMOS transistor employing a layer formed of materials having a high dielectric constant, desired Vth values, which are values required in the NMOS transistor and the PMOS transistor, can be obtained by forming different layers each containing specific materials allowing for the regulation of Vth to a desired value at interfaces between the gate dielectric layer and the active area of the NMOS transistor, and the gate dielectric layer and the active area of the PMOS transistor to overcome a Vth unbalance in different types of channels. Accordingly, when the semiconductor device is fabricated with a layer formed of materials having a high dielectric constant constituting the gate dielectric layer, the semiconductor device can be provided by obtaining the desired Vth without degradation of a mobility property and the reliability of each of the NMOS transistor and the PMOS transistor.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A semiconductor device comprising:
a semiconductor substrate comprising an active area where a first conductive channel is formed;
a gate electrode formed on the active area of the semiconductor substrate;
a gate dielectric layer interposed between the active area and the gate electrode; and
a charge generating layer formed along the interface between the active area and the gate dielectric layer on the semiconductor substrate so that fixed charges are generated around the interface.

2. The semiconductor device of claim 1, wherein the active area is formed in an N-type well of the semiconductor substrate, the charge generating layer is formed along the interface in the N-type well, and the charge generating layer comprises a first lattice structure which is different from a second lattice structure of the semiconductor substrate in another part of the N-type well.

3. The semiconductor device of claim 2, wherein the first lattice structure of the charge generating layer comprises a dopant formed of (F), germanium (Ge) or combination thereof.

4. The semiconductor device of claim 1, wherein the first conductive channel is a P-type channel, and the charge generating layer comprises a dopant formed of fluorine (F), germanium (Ge) or combination thereof.

5. The semiconductor device of claim 1, wherein negative fixed charges exist around the interface between the active area and the gate dielectric layer.

6. The semiconductor device of claim 1, wherein the gate dielectric layer is formed of a material selected from the group consisting of hafnium oxide (HfO₂), zirconium oxide (ZrO₂), aluminum oxide (Al₂O₃), titanium oxide (TiO₂), lanthanum oxide (La₂O₃), yttrium oxide (Y₂O₃), gadolinium oxide (Gd₂O₃), tantalum oxide (Ta₂O₅), aluminate, metal silicate, and combinations thereof.

7. The semiconductor device of claim 1, wherein the gate electrode is formed of a material selected from the group consisting of polysilicon, a metal, a metal nitride, a metal silicide, and combinations thereof.

8. The semiconductor device of claim 1, wherein the gate electrode comprises a stack structure comprising a metal nitride layer and a polysilicon layer.

9. The semiconductor device of claim 8, wherein the metal nitride layer has a thickness in the range of about 10 through about 100 Å, and the poly silicon layer has a thickness in the range of about 1000 through about 1500 Å.

10. A semiconductor device comprising:
a semiconductor substrate comprising an active area of an n-channel metal oxide semiconductor (NMOS) transistor and an active area of a p-channel metal oxide semiconductor (PMOS) transistor;
a first gate electrode formed on the active area of the NMOS transistor;
a second gate electrode formed on the active area of the PMOS transistor;
a first gate dielectric layer interposed between the semiconductor substrate and the first gate electrode;
a second gate dielectric layer interposed between the semiconductor substrate and the second gate electrode;
a nitrogen implantation region formed along an interface between the active area of the NMOS transistor and the first gate dielectric layer on the semiconductor substrate; and
a charge generating layer formed along an interface between the active area of the PMOS transistor and the second gate dielectric layer on the semiconductor substrate.

11. The semiconductor device of claim 10, wherein the charge generating layer comprises a first lattice structure which is different from a second lattice structure of the semiconductor substrate in another part of the active area of the PMOS transistor.

12. The semiconductor device of claim 11, wherein the first lattice structure of the charge generating layer comprises a dopant formed of fluorine (F), germanium (Ge) or combination thereof.

13. The semiconductor device of claim 10, wherein negative fixed charges exist around the interface between the active areas and the gate dielectric layer.

14. The semiconductor device of claim 10, wherein the first gate dielectric layer and the second gate dielectric layer are each formed of a material selected from the group consisting of hafnium oxide (HfO₂), zirconium oxide (ZrO₂), aluminum oxide (Al₂O₃), titanium oxide (TiO₂), lanthanum oxide (La₂O₃), yttrium oxide (Y₂O₃), gadolinium (Gd₂O₃), tantalum oxide (Ta₂O₅), aluminate, metal silicate, and combinations thereof.

15. The semiconductor device of claim 10, wherein the first gate electrode and the second electrode are formed of a material selected from the group consisting of poly silicon, a metal, a metal nitride, a metal silicide, and combinations thereof.

16. The semiconductor device of claim 10, wherein the first gate electrode and the second gate electrode each comprises a stack structure comprising a metal nitride layer and a polysilicon layer.

17. The semiconductor device of claim 16, wherein the metal nitride layer has a thickness in the range of about 10 through about 100 Å, and the poly silicon layer has a thickness in the range of about 1000 through about 1500 Å.

18. A method of fabricating a semiconductor device, the method comprising:
forming a first conductive type well by ion-implanting a first dopant into a semiconductor substrate;
forming a charge generating layer on the surface of the first conductive type well by implanting a fixed charge generation material in the first conductive type well;
forming a gate dielectric layer on the charge generating layer;
forming a gate electrode on the gate dielectric layer; and
forming a source/drain region on both sides of the gate electrode in the conductive type well by implanting a second impurity of a second conductive type into the first conductive type well.

19. The method of claim 18, wherein the forming of the charge generating layer comprises:
covering an upper surface of the first conductive type well with a protection layer before implanting the fixed charge generation material; and
removing the protection layer after implanting the fixed charge generation material.

20. The method of claim 18, wherein the first conductive type well is an N-type well, the second conductive type well is a P-type well, and the fixed charge generation material is formed of fluorine (F), germanium (Ge) or combination thereof.

21. The method of claim 18, further comprising:
heat-treating the semiconductor substrate for activating the fixed charge generation material after implanting the fixed charge generation material into the first conductive type well.

22. The method of claim 18, wherein the charge generating layer is formed by implanting the fixed charge generation material into the conductive type well with a dose in the range of about 1E14 through about 1E16 ion/cm² and an energy in the range of about 5 through about 50 KeV.

23. The method of claim 18, further comprising:
implanting a third dopant into the first conductive type well for regulating a threshold voltage of a transistor comprising the gate electrode before implanting the fixed charge generation material into the first conductive type well.

24. The method of claim 18, wherein the gate dielectric layer is formed of a material selected from the group consisting of hafnium oxide (HfO₂), zirconium oxide (ZrO₂), aluminum oxide (Al₂O₃), titanium oxide (TiO₂), lanthanum oxide (La₂O₃), yttrium oxide (Y₂O₃), gadolinium oxide (Gd₂O₃), tantalum oxide (Ta₂O₅), aluminate, metal silicate, and combinations thereof.

25. The method of claim 18, wherein the gate electrode is formed of a material selected from the group consisting of polysilicon, a metal, a metal nitride, a metal silicide, and combinations thereof.

26. The method of claim 18, wherein the gate electrode comprises a stack structure comprising a metal nitride layer and a polysilicon layer.

27. The method of claim 26, wherein the metal nitride layer is formed to have a thickness in the range of about 10 through about 100 Å, and the polysilicon layer is formed to have a thickness in the range of about 1000 through about 1500 Å.

28. A method of fabricating a semiconductor device, the method comprising:
preparing a semiconductor substrate comprising an active area of an n-channel metal oxide semiconductor (NMOS) transistor and an active area of a p-channel metal oxide semiconductor (PMOS) transistor;
forming a nitrogen implantation region on only the active area of the NMOS transistor on the semiconductor substrate;
forming a charge generating layer on only the active area of the PMOS transistor on the semiconductor substrate;
forming a first gate dielectric layer and a second gate dielectric layer on the nitrogen implantation region on the active area of the NMOS transistor and the charge generating layer on the active area of the PMOS transistor, respectively;
forming a first gate electrode and a second gate electrode on the gate dielectric layer on the active area of the NMOS transistor and the active area of the PMOS transistor, respectively; and
forming a first source/drain region arranged at both sides of the first gate electrode on the active area of the NMOS transistor, and a second source/drain region arranged at both sides of the second gate electrode on the active area of the PMOS transistor.

29. The method of claim 28, wherein the forming of the charge generating layer comprises implanting a fixed charge generation material formed of fluorine (F), germanium (Ge), or combination thereof into the PMOS transistor region.

30. The method of claim 29, further comprising:
heat-treating the semiconductor substrate for activating the fixed charge generation material after implanting the fixed charge generation material into the active area of the PMOS transistor.

31. The method of claim 29, wherein the forming of the charge generating layer comprises:
covering an upper surface of the first conductive type well with a protection layer before implanting the fixed charge generation material; and
removing the protection layer after implanting the fixed charge generation material.

32. The method of claim 28, wherein the forming of the nitrogen implantation region is performed using one of an ion-implanting method, a heat treatment under a nitrogen containing atmosphere, or a plasma-enhanced nitridation method.

33. The method of claim 28, wherein the forming of the nitrogen implantation region comprises implanting nitrogen atoms or nitrogen molecules into the active area of the NMOS transistor with a dose in the range of about 1E14 through about 1E16 ion/cm² and an energy in the range of about 5 through about 3 KeV.

34. The method of claim 28, wherein the first gate dielectric layer and the second gate dielectric layer each are formed of a material selected from the group consisting of hafnium oxide (HfO₂), zirconium oxide (ZrO₂), aluminum oxide (Al₂O₃), titanium oxide (TiO₂), lanthanum oxide (La₂O₃), yttrium oxide (Y₂O₃), gadolinium oxide (Gd₂O₃), tantalum oxide (Ta₂O₅), aluminate, metal silicate, and combinations thereof.

35. The method of claim 28, wherein the first gate electrode and the second gate electrode are each formed of a material selected from the group consisting of polysilicon, a metal, a metal nitride, a metal silicide, and combinations thereof.

36. The method of claim 28, wherein the first gate electrode and the second electrode each comprise a stack structure comprising a metal nitride layer and a polysilicon layer.

37. The method of claim 36, wherein the metal nitride layer is formed to have a thickness in the range of about 10 through about 100 Å, and the polysilicon layer is formed to have a thickness in the range of about 1000 through about 1500 Å.
